(19) United States
(12) Patent Application Publication
(10) Pub. No.: US 2006/0076564 A1
(43) Pub. Date: Apr. 13, 2006

(54) Gallium-nitride based semiconductor device buffer layer structure

(76) Inventors: Liang-Wen Wu, Banciao City (TW); Ru-Chin Tu, Tainan City (TW); Cheng-Tsang Yu, Wufong Township (TW); Tzu-Chi Wei, Tainan City (TW); Fen-Ren Chien, Banciao City (TW)

Correspondence Address: SUPREME PATENT SERVICES, P.O. BOX 2339, SARATOGA, CA, 95070-0339, US

(21) Appl. No.: 10/964,348

(22) Filed: Oct. 12, 2004

(51) Int. Cl. H01L 33/00

(52) U.S. Cl. 257/79

(57) ABSTRACT

A buffer layer structure for the GaN-based semiconductor devices is provided. The buffer layer proposed by the present invention comprises internally at least two sub-layers: a first intermediate layer and a second intermediate layer. Initially, the first intermediate layer is developed on the substrate under a low temperature using silicon-nitride (SiₓN_{y}, x,y≧0). The first intermediate layer is actually a mask having multiple randomly distributed SiₓN_{y} clusters. Then, a second intermediate layer is developed under a low temperature using aluminum-indium-gallium-nitride (Al_{w}In_{z}Ga_{1-w-z}N, 0≦w,z<1, w+z≦1). The second intermediate layer does not grow directly on top of the first intermediate layer. Instead, the second intermediate layer first grows from the surface of the substrate not covered by the first intermediate layer's mask and, then, overflows to cover the top of the first intermediate layer. The buffer layer according to the present invention effectively reduces the defect density of the GaN-based semiconductor devices.

### BACKGROUND OF THE INVENTION

1. Field of the Invention

The present invention generally relates to the gallium-nitride based semiconductor devices and, more particularly, to the structure of the buffer layer of the gallium-nitride based semiconductor devices.

2. The Prior Arts

Gallium-nitride (GaN) based semiconductor devices, such as blue or purple GaN-based light emitting diodes (LEDs), or GaN-based photo diodes capable of detecting ultra-violet lights, have been in recent years the research and development focus in the academic and industrial arena due to the devices' wide band gap characteristics.

Conventionally, these GaN-based semiconductor devices usually have a buffer layer made of aluminum-nitride (AlN) or GaN developed under a low temperature (between 200° C. and 900° C.) on top of a substrate. Then, on top of the buffer layer, the major epitaxial structure of the GaN-based semiconductor devices is developed under high temperatures. The reason for having such a buffer layer is mainly due to that the substrate and the major epitaxial structure of the GaN-based semiconductor devices have significantly different lattice constants. Without this buffer layer, excessive stress resulted from the piezoelectric effect will be accumulated, causing the major epitaxial structure of the GaN-based semiconductor device to have an inferior epitaxial quality.

However, the AlN or GaN buffer layer developed under a low temperature also results in a number of shortcomings to the GaN-based semiconductor devices, such as high defect density (more than 10e10/cm³), limited operation life, low resistivity to electrostatic discharge (ESD), etc.

### SUMMARY OF THE INVENTION

Accordingly, the present invention is directed to provide a buffer layer structure for the GaN-based semiconductor devices so that the limitations and disadvantages from the prior arts can be obviated practically.

The buffer layer proposed by the present invention comprises internally two sub-layers: a first intermediate layer and a second intermediate layer. Initially, the first intermediate layer is developed on the substrate under a low temperature using silicon-nitride (SiₓN_{y}, x,y≧0). FIG. 1 of the attached drawings is a top schematic view of the GaN-based semiconductor device according to the present invention after the first intermediate layer is developed. As shown in FIG. 1, the first intermediate layer is actually a mask having multiple, randomly distributed SiₓN_{y} clusters. Then, a second intermediate layer is developed under a low temperature using aluminum-indium-gallium-nitride (Al_{w}In_{z}Ga_{1-w-z}N, 0≦w,z<1, w+z≦1). Please note that the second intermediate layer does not grow directly on top of the first intermediate layer. Instead, the second intermediate layer first grows from the surface of the substrate not covered by the first intermediate layer's mask and, then, overflows to the top of the first intermediate layer, in a manner called Epitaxially Lateral Overgrowth (ELOG). The multi-layered buffer layer developed in the ELOG fashion according to the present invention effectively reduces the defect density of the GaN-based semiconductor devices, as compared to the traditional AlN or GaN buffer layer developed under a low temperature.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 is a top schematic view of the GaN-based semiconductor device according to the present invention after the first intermediate layer is developed.

FIG. 2 is a schematic diagram showing the epitaxial structure of a GaN-based semiconductor device according to the first embodiment of the present invention.

FIG. 3 is a schematic diagram showing the epitaxial structure of a GaN-based semiconductor device according to the second embodiment of the present invention.

FIG. 4 is a schematic diagram showing the epitaxial structure of a GaN-based semiconductor device according to the third embodiment of the present invention.

FIG. 5 is a schematic diagram showing the epitaxial structure of a GaN-based semiconductor device according to the fourth embodiment of the present invention.

### DETAILED DESCRIPTION OF THE PREFERRED EMBODIMENTS

In the following, detailed description along with the accompanied drawings is given to better explain preferred embodiments of the present invention. Please be noted that, in the accompanied drawings, some parts are not drawn to scale or are somewhat exaggerated, so that people skilled in the art can better understand the principles of the present invention.

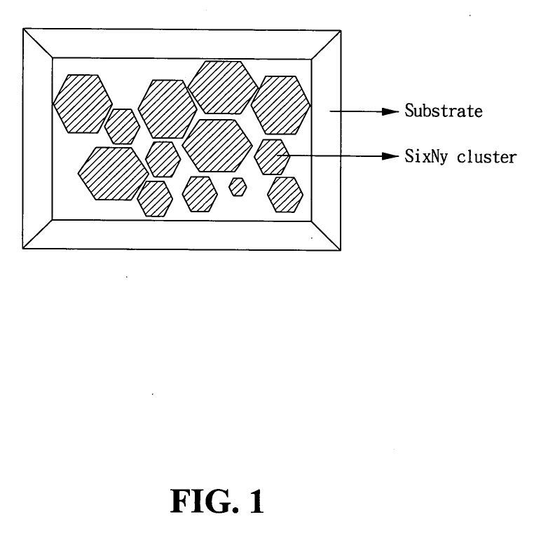

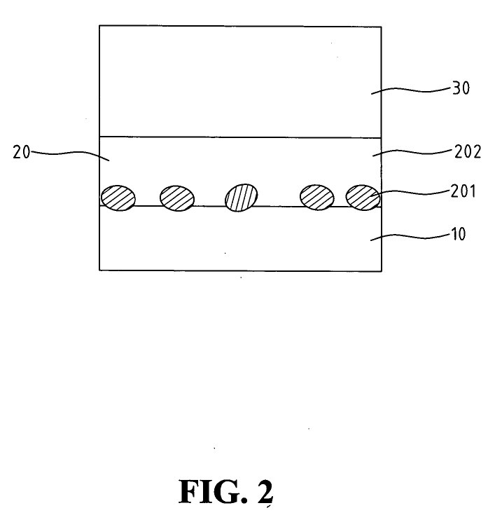

FIG. 2 is a schematic diagram showing the epitaxial structure of a GaN-based semiconductor device according to the first embodiment of the present invention. As in conventional GaN-based semiconductor devices, the substrate 10 depicted in FIG. 1 is made of C-plane, R-plane, or A-plane aluminum-oxide monocrystalline (sapphire), or an oxide monocrystalline having a lattice constant compatible with that of nitride semiconductors. The substrate 10 can also be made of SiC (6H—SiC or 4H—SiC), Si, ZnO, GaAs, or MgAl₂O₄. Generally, the most common material used for the substrate 10 is sapphire or SiC. As shown in FIG. 2, the GaN-based semiconductor device then has a buffer layer 20 formed on top of an upper side of the substrate 10. Subsequently, the major epitaxial structure 30 of the GaN-based semiconductor device is formed on top of the buffer layer 20.

As shown in FIG. 2, the buffer layer 20 comprises a first intermediate layer 201 and a second intermediate layer 202. First, the first intermediate layer 201 is developed on top of the substrate 10 using SiₐN_{b} (a,b≧0) of a specific composition through a Metallic Organic Chemical Vapor Deposition (MOCVD) process under a low temperature between 200° C. and 700° C. The first intermediate layer 201 then forms a mask having a thickness between 5 Å and 100 Å, and contains multiple randomly distributed SiₐN_{b} clusters on top of the substrate 10. Secondly, the second intermediate layer 202 is developed using Al_{c}In_{d}Ga_{1-c-d}N (0≦c,d<1, c+d≦1) of a specific composition through a MOCVD process under a low temperature between 400° C. and 700° C. to a thickness between 50 Å and 400 Å. In fact, the second intermediate layer 202 does not grow directly on top of the first intermediate layer 201. Instead, in an ELOG manner, the second intermediate layer 202's Al_{c}In_{d}Ga_{1-c-d}N grows from the surface of the substrate 10 not covered by the mask of the first intermediate layer 201, and then overflows to cover the top of the mask of the first intermediate layer 201.

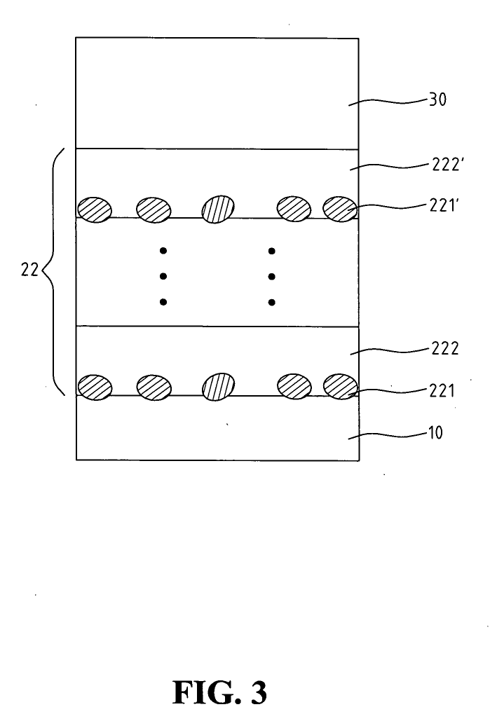

FIG. 3 is a schematic diagram showing the epitaxial structure of a GaN-based semiconductor device according to the second embodiment of the present invention. Similar to the previous first embodiment of the present invention, the first intermediate layer 221 is developed on top of the substrate 10 using SiₑN_{f} (e,f≧0) through a Metallic Organic Chemical Vapor Deposition (MOCVD) process under a low temperature between 200° C. and 700° C. The first intermediate layer 221 then forms a mask having a thickness between 5 Å and 20 Å, and contains multiple randomly distributed SiₑN_{f} clusters on top of the substrate 10. Then, the second intermediate layer 222 is developed using Al_{g}InₕGa_{1-g-h}N (0≦g,h<1, g+h≦1) through a MOCVD process under a low temperature between 400° C. and 700° C. to a thickness between 10 Å and 100 Å. Similarly, the second intermediate layer 222 does not grow directly on top of the first intermediate layer 221. Instead, in an ELOG manner, the second intermediate layer 222's Al_{g}InₕGa_{1-g-h}N grows from the surface of the substrate 10 not covered by the mask of the first intermediate layer 221, and then overflows to cover the top of the mask of the first intermediate layer 221.

Then, another pair of the first intermediate layer 221′ and the second intermediate layer 222′ are developed using the same process as in the formation of the first pair of the first and second intermediate layers 221 and 222. The process are repeated multiple times so that the buffer layer 22 comprises 2 to 10 pairs of the first and second intermediate layers 221 and 222. Within the buffer layer 22, each of the first intermediate layers 221 has its specific thickness and material composition (i.e. the parameters e and f of the SiₑN_{f} in each first intermediate layer 221 are not required to be identical). Similarly, each of the second intermediate layers 222 has its specific thickness and composition (i.e. the parameters g and h of the Al_{g}InₕGa_{1-g-h}N in each second intermediate layer 222 are not required to be identical).

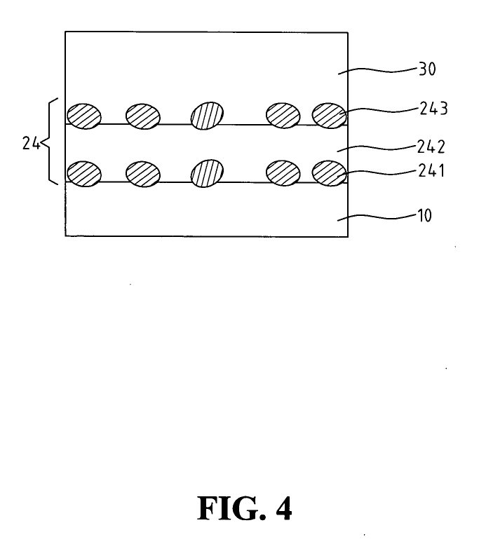

FIG. 4 is a schematic diagram showing the epitaxial structure of a GaN-based semiconductor device according to the third embodiment of the present invention. As shown in FIG. 4, the buffer layer 24 is very similar to the buffer layer 20 in the first embodiment of the present invention. Within the buffer layer 24, the same MOCVD process is conducted to develop the first intermediate layer 241 using SiᵢNⱼ (i,j≧0) of a specific composition under a low temperature between 200° C. and 700° C. The first intermediate layer 241 also forms a mask having a thickness between 5 Å and 100 Å, and contains multiple randomly distributed SiᵢNⱼ clusters on top of the substrate 10. Similarly, a second intermediate layer 242 is developed, in an ELOG manner, to cover the first intermediate layer 241 using AlₘInₙGa₁₋ₘ₋ₙN (0≦m,n<1, m+n≦1) of a specific composition through a MOCVD process under a low temperature between 400° C. and 700° C. to a thickness between 50 Å and 400 Å.

Then, the buffer layer 24 further comprises a third intermediate layer 243 developed using SiₖNₒ (k,o≧0) of a specific composition through a MOCVD process under a low temperature 200° C. and 700° C. The third intermediate layer 243 again forms a mask having a thickness between 5 Å and 100 Å, and contains multiple randomly distributed SiₖNₒ clusters on top of the second intermediate layer 242. Then, the major epitaxial structure 30 of the GaN-based semiconductor device is subsequently developed. The epitaxial structure 30 grows in an ELOG manner from the surface of the second intermediate layer 242 not covered by the mask of the third intermediate layer 243, and then overflows to cover the top of the mask of the third intermediate layer 243. The first intermediate layer 241's SiᵢNⱼ and the third intermediate layer 243's SiₖNₒ are not required to have identical compositions.

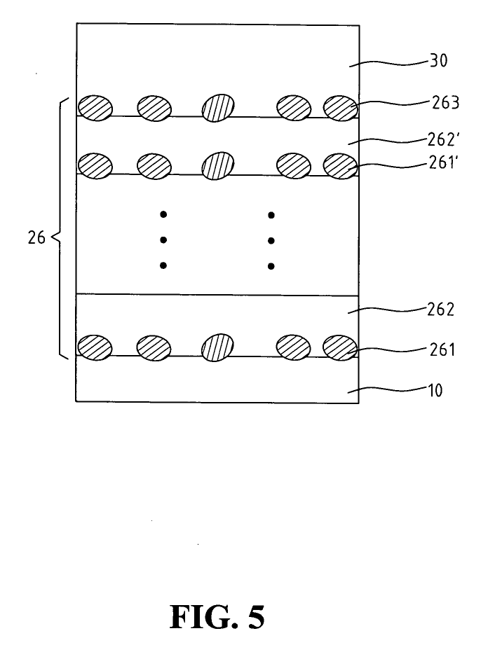

FIG. 5 is a schematic diagram showing the epitaxial structure of a GaN-based semiconductor device according to the fourth embodiment of the present invention. As shown in FIG. 5, the buffer layer 26 is very similar to the buffer layer 22 of the second embodiment of the present invention. Using the same development process, materials, and under the same temperature and thickness conditions, the buffer layer 26 comprises 2˜10 pairs of the first intermediate layer 261 and the second intermediate layer 262, with each intermediate layer having its specific thickness and material composition. Then, the buffer layer 26 further comprises a third intermediate layer 263 developed using SiₚN_{q} (p,q≧0) of a specific composition through a MOCVD process under a low temperature 200° C. and 700° C. The third intermediate layer 263 again forms a mask having a thickness between 5 Å and 20 Å, and contains multiple randomly distributed SiₚN_{q} clusters on top of the topmost second intermediate layer 262.

Then, the major epitaxial structure 30 of the GaN-based semiconductor device is subsequently developed under a high temperature. The epitaxial structure 30 grows in an ELOG manner from the surface of the topmost second intermediate layer 262 not covered by the mask of the third intermediate layer 263, and then overflows to cover the top of the mask of the third intermediate layer 263.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A buffer layer for a GaN-based semiconductor device, located on top of an upper side of said GaN-based semiconductor device's substrate made of a material selected from the group consisting of sapphire, 6H—SiC, 4H—SiC, Si, ZnO, GaAs, MgAl₂O₄, and an oxide monocrystalline having a lattice constant compatible with that of nitride semiconductors, and upon which said GaN-based semiconductor device's major epitaxial structure is developed, comprising:
a first intermediate layer, located on top of said upper side of said substrate and made of SiₐN_{b} (a,b≧0) of a specific composition, having a plurality of randomly distributed SiₐN_{b} clusters and a thickness between 5 Å and 1000 Å; and
a second intermediate layer, made of Al_{c}In_{d}Ga_{1-c-d}N (0≦c,d<1, c+d≦1) of a specific composition and developed from a part of said upper side of said substrate not covered by said first intermediate layer to grow over said first intermediate layer, having a thickness between 50 Å and 400 Å.

2. The buffer layer for a GaN-based semiconductor device as claimed in claim 1, wherein said buffer layer further comprises a third intermediate layer that is located on top of said second intermediate layer, is made of SiₖNₒ (k,o≧0) of a specific composition, has a plurality of randomly distributed SiₖNₒ clusters, and has a thickness between 5 Å and 100 Å.

3. A buffer layer for a GaN-based semiconductor device, located on top of an upper side of said GaN-based semiconductor device's substrate made of a material selected from the group consisting of sapphire, 6H—SiC, 4H—SiC, Si, ZnO, GaAs, MgAl₂O₄, and an oxide monocrystalline having a lattice constant compatible with that of nitride semiconductors, and upon which said GaN-based semiconductor device's major epitaxial structure is developed, comprising a plurality of pairs of intermediate layers, sequentially stacked on top of said upper side of said substrate, wherein each pair intermediate layers further comprises:
a first intermediate layer, made of SiₑN_{f} (e,f≧0) of a specific composition, having a plurality of randomly distributed SiₑN_{f} clusters and a thickness between 5 Å and 20 Å; and
a second intermediate layer, made of Al_{g}InₕGa_{1-g-h}N (0≦g,h<1, g+h≦1) of a specific composition and developed from a surface beneath but not covered by said first intermediate layer to grow over said first intermediate layer, having a thickness between 10 Å and 1000 Å.

4. The buffer layer for a GaN-based semiconductor device as claimed in claim 3, wherein said buffer layer further comprises a third intermediate layer that is located on top of a topmost one of said second intermediate layer, is made of SiₚN_{q} (p,q≧0) of a specific composition, has a plurality of randomly distributed SiₚN_{q} clusters, and has a thickness between 5 Å and 1000 Å.

5. The buffer layer for a GaN-based semiconductor device as claimed in claim 3, wherein said plurality of pairs of intermediate layers comprises 2 to 10 pairs of said first and second intermediate layers.

6. The buffer layer for a GaN-based semiconductor device as claimed in claim 3, wherein each of said first intermediate layers has its specific material composition and thickness independent from each other, and each of said second intermediate layers has its specific material composition and thickness independent from each other.
